(19) United States
(12) Patent Application Publication
(10) Pub. No.: US 2021/0359124 A1
(43) Pub. Date: Nov. 18, 2021

(54) SCHOTTKY CONTACT REGION FOR HOLE INJECTION SUPPRESSION

(71) Applicant: Monolithic Power Systems, Inc., San Jose, CA (US)

(72) Inventors: Eric Braun, Mountain View, CA (US); Kee Chee Tiew, Cupertino, CA (US); Ji-Hyoung Yoo, Los Gatos, CA (US)

(21) Appl. No.: 15/930,427

(22) Filed: May 12, 2020

(51) Int. Cl. H01L 29/78; H01L 29/06; H01L 29/10

(52) U.S. Cl. CPC H01L 29/782; H01L 29/7823; H01L 29/1095; H01L 29/0623

(57) ABSTRACT

A power transistor having: a p-body region, coupled to a first voltage; a first p-type buried layer under the p-body region; a n-implant region surrounding the p-body region and the p-type buried layer; a p-implant region surrounding the n-implant region; and a p-implant guard ring region inserted into the n-implant region to split the n-implant region to a first part and a second part, wherein the first part of the n-implant region is between the p-body region and the p-implant guard ring region, and the second part of the n-implant region is between the p-implant guard ring region and the p-implant region; wherein the second part of the n-implant region has a Schottky contact region coupled to a second voltage via a metal contact.

### TECHNICAL FIELD

The present invention relates generally to power transistors, and more particularly, to a Schottky diode structure incorporated with power transistors to reduce parasitic effects.

### BACKGROUND

MOS transistors are typically fabricated in an IC chip which is adopted to control an inductive load. The semiconductor structure of the MOS transistor gives rise to parasitic effects which, under the appropriate conditions, may degrade the performance of the transistor, or disable the transistor.

FIG. 1a schematically shows a prior art standard high side connected power N type DMOS (nDMOS) transistor M1 in a switching mode application, and FIG. 1b shows a cross section view of the semiconductor structure of the power nDMOS transistor M1 in FIG. 1a. As can be seen from FIG. 1b, a p-body 107 and p-type buried layer 105-1 are enclosed in n-type regions 102 and 103, which are further enclosed by p-type regions 106, 105-2, 104 and 101. Importantly, drain 109 and n-implant region 103 are tied to Vin respectively through contact regions 110 and 111. Source 114 and body contact 113 are tied to a voltage Vsw, and p-well contact 112 is tied to a voltage GND. In the switching mode application, the voltage Vsw at a switching node may be sometimes higher than the input voltage Vin due to a forward conducted body diode D0 of the nDMOS transistor M1. In that case, the inner p-body 107 and p-type buried layer 105-1 become unintentionally forward biased relative to the enclosing n-type regions 102 and 103, and holes are injected from the body contact 113 (Vsw) into the regions 102 and 103 (Vin) and collected by the p-type regions 106, 105-2, 104 and 101 (GND). Then a parasitic PNP transistor Q1 (emitter=inner p-type regions 107 and 105-1, base=enclosing n-implant regions 102 and 103, collector=enclosing p-type regions 106, 105-2, 104 and 101) as shown in FIGS. 1a and 1b may be activated. That introduces several operational and reliability concerns: 1) A collection path across high voltage between the emitter and the collector of the PNP transistor Q1 can dissipate a high amount power loss of Pdissipate=Icollection*Vce, wherein (collection represents a current flowing through the parasitic PNP transistor Q1, and Vce represents a voltage between the collector and the emitter of the PNP transistor Q1, that can additionally induce localized, non-uniform temperature gradients and related undesirable device and circuit affects; 2) The collected current can lift the collector a voltage of V=Icollector×Rcollector locally or globally with a magnitude depending on the collector resistance Rcollector, that can disturb or induce latch up in other devices with n-type regions, either enclosed or abutting the collector, through capacitive displacement current flow and/or a junction forward bias parasitic NPN transistor turn-on.

Thus, there is a need to suppress the parasitic PNP transistor Q1.

### SUMMARY

It is an object of the present invention to suppress unintentional hole injection activating a parasitic PNP transistor in a power transistor.

In accomplishing the above objective, there has been provided, in accordance with an embodiment of the present invention, a power transistor comprising: a p-body region, coupled to a first voltage; a first p-type buried layer under the p-body region; a n-implant region surrounding the p-body region and the p-type buried layer; a p-implant region surrounding the n-implant region; and a p-implant guard ring region inserted into the n-implant region to split the n-implant region to a first part and a second part, wherein the first part of the n-implant region is between the p-body region and the p-implant guard ring region, and the second part of the n-implant region is between the p-implant guard ring region and the p-implant region; wherein the second part of the n-implant region has a Schottky contact region coupled to a second voltage via a metal contact.

In accomplishing the above objective, there has been provided, in accordance with an embodiment of the present invention, a power transistor comprising: a first p-implant region, coupled to a first voltage; a n-implant region surrounding the p-implant region, coupled to a second voltage; and a second p-implant region surrounding the n-implant region; wherein the n-implant region has a Schottky contact region coupled to the second voltage via a metal contact.

In accomplishing the above objective, there has been provided, in accordance with an embodiment of the present invention, a power transistor comprising: a first p-implant region, coupled to a first voltage; a n-implant region surrounding the p-implant region, coupled to a second voltage; a second p-implant region surrounding the n-implant region; and a p-implant guard ring region inserted into the n-implant region to split the n-implant region into a first part and a second part, wherein the first part of the n-implant region is between the first p-implant region and the p-implant guard ring region, and the second part of the n-implant region is between the p-implant guard ring region and the second p-implant region; wherein the second part of the n-implant region has a first Schottky contact region coupled to the second voltage via a metal contact.

### BRIEF DESCRIPTION OF THE DRAWINGS

Non-limiting and non-exhaustive embodiments are described with reference to the following drawings. The drawings are only for illustration purpose. Usually, the drawings only show part of the devices of the embodiments. These drawings are not necessarily drawn to scale. The relative sizes of elements illustrated by the drawings may differ from the relative size depicted.

FIG. 1a schematically shows a prior art standard high side connected power nDMOS transistor M1 in a switching mode application;

FIG. 1b shows a cross section view of the semiconductor structure of the power nDMOS transistor M1 in FIG. 1a.

FIG. 2 schematically shows a cross section view of a semiconductor structure of a power transistor 200 in accordance with an embodiment of the present invention.

FIG. 3 schematically shows a cross section view of a semiconductor structure of a power transistor 300 in accordance with an embodiment of the present invention.

FIG. 4 schematically shows a cross section view of a semiconductor structure of a power transistor 400 in accordance with an embodiment of the present invention.

FIG. 5 schematically shows a cross section view of a semiconductor structure of a power transistor 500 in accordance with an embodiment of the present invention.

FIG. 6 schematically shows a cross section view of a semiconductor structure of a power transistor 600 in accordance with an embodiment of the present invention.

FIG. 7 schematically shows a cross section view of a semiconductor structure of a power transistor 700 in accordance with an embodiment of the present invention.

FIG. 8 schematically shows a cross section view of a semiconductor structure of a power transistor 800 in accordance with an embodiment of the present invention.

FIG. 9 schematically shows a cross section view of a semiconductor structure of a power transistor 900 in accordance with an embodiment of the present invention.

The use of the same reference label in different drawings indicates the same or like components.

### DETAILED DESCRIPTION

The following description provides exemplary embodiments of the technology. One skilled in the art will understand that the technology may be practiced without some or all of the features described herein. In some instances, well known structures and functions have not been shown or described in detail to avoid unnecessarily obscuring the description of the embodiments of the technology. In some instances, similar structures and functions that have been described in detail for other embodiments are not been described in detail for such embodiments to simplify and make clear understanding of the embodiments. It is intended that the terminology used in the description presented below be interpreted in its broadest reasonable manner, even though it is being used in conjunction with a detailed description of certain embodiments of the technology.

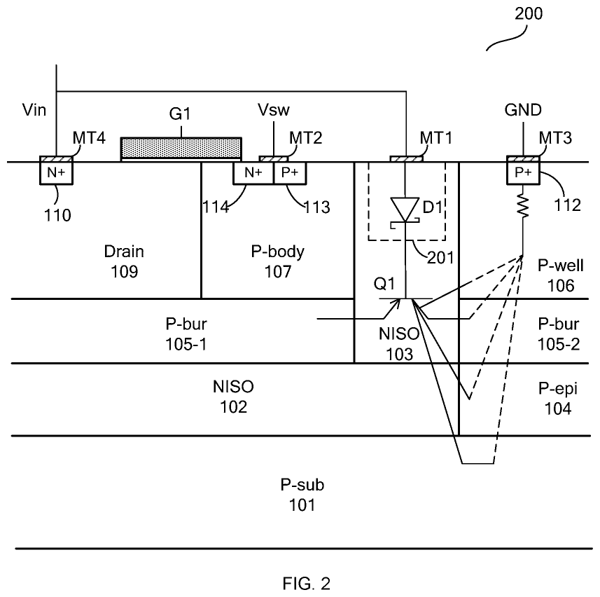

FIG. 2 schematically shows a cross section view of a semiconductor structure of a power transistor 200 in accordance with an embodiment of the present invention. The power transistor 200 may be used as a power switch in a switching converter. As shown in FIG. 2, the power transistor 200 comprises: a p-type substrate 101, a n-type isolation layer 102, a n-type isolation region 103, a p-type epitaxial layer 104, p-type buried layer 105-1 and 105-2, p-body 107, p-well (p-type well region) 106, a n+ implant region (source) 114, a drain 109. The source 114 and a body pick up region 113 are connected to a switching voltage Vsw (also referred as a first voltage) via a metal contact MT2. The drain 109 is connected to an input voltage Vin (also referred as a second voltage) via a contact region 110 and a metal contact MT4. The n-type isolation layer 102 and n-type isolation region 103 are connected to the input voltage Vin via a metal contact MT1. The p-type substrate 101, the p-type epitaxial layer 104, the p-type buried layer 105-2 and the p-well (p-type well region) 106 are connected to a ground reference voltage GND (also referred as a third voltage).

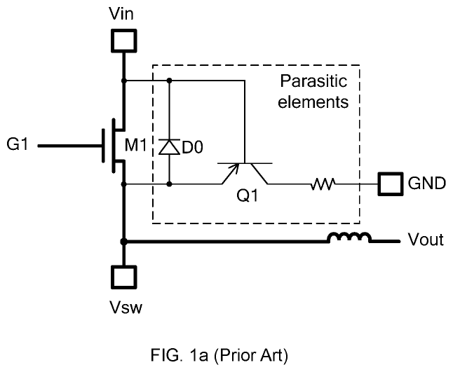

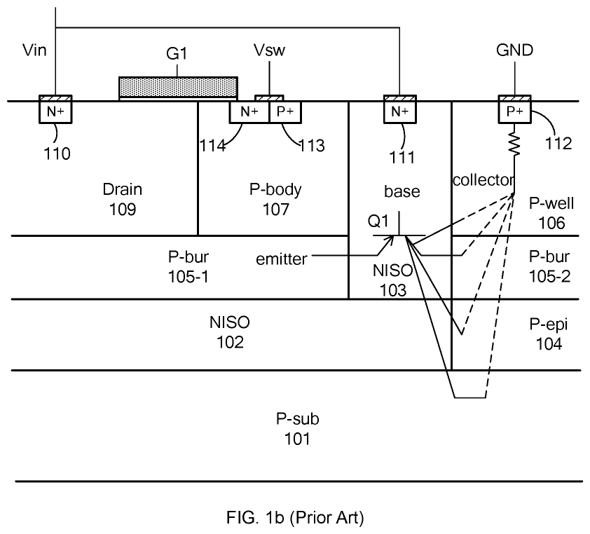

As can be seen from FIG. 2, the p-body 107 and the p-type buried layer 105-1 form a first p-implant region coupled to the switching voltage Vsw. The n-type isolation layer 102 and the n-type isolation region 103 form a n-implant region coupled to the input voltage Vin. The p-type substrate 101, the p-type epitaxial layer 104, the p-type buried layer 105-2 and the p-well 106 form a second p-implant region coupled to the ground reference voltage GND. The first p-implant region, the n-implant region and the second p-implant region make a parasitic PNP transistor Q1 as shown in FIG. 2. When the switching voltage Vsw is higher than the input voltage Vin under some circumstances, the PNP transistor Q1 is activated. In the embodiment of FIG. 2, to suppress the conductance of the PNP transistor Q1, a Schottky contact region 201 is replacing the ohmic contact region 111 in FIG. 1b to the n-type isolation region 103, which forms a Schottky diode D1, with the metal contact MT1 being an anode and the n-implant region under the metal contact MT1 being a cathode. It should be understood that the Schottky contact region 201 could be any semiconductor material with appropriate concentration to form a Schottky diode with a metal region, and the region 201 is only for indication, not showing the real area of the Schottky contact region. When the switching voltage Vsw exceeds the input voltage Vin, the Schottky diode D1 force the injected hole recombination current in the base to charge up the base region to de-bias the emitter-base junction and suppress further hole injection and associated collection by the surrounding or abutting p-type regions.

In some embodiments, the p-type epitaxial layer 104 is not necessary, and could be replaced by the p-type substrate 101.

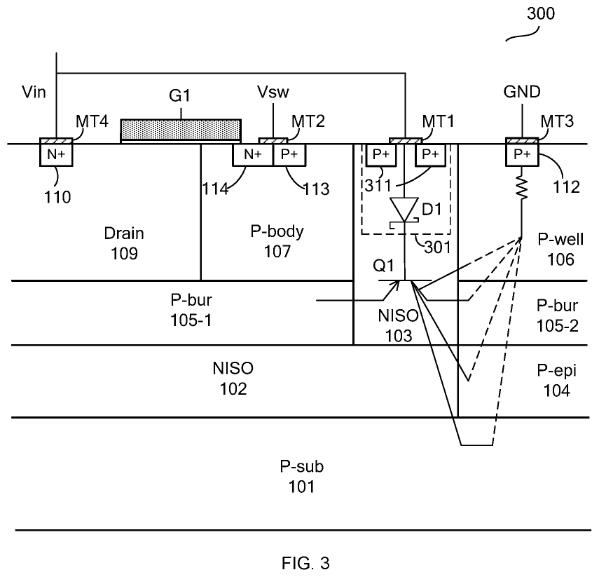

FIG. 3 schematically shows a cross section view of a semiconductor structure of a power transistor 300 in accordance with an embodiment of the present invention. As shown in FIG. 3, the n-type isolation region 103 further comprises a p-type contact region 311 located in a surface of the n-type isolation region 103, wherein part of the p-type contact region 311 is underneath the metal contact MT1 of the n-type isolation region 103.

In the example of FIG. 3, part of the p-type contact region 311 is underneath the metal contact MT1. In other embodiments, the whole part of the p-type contact region 311 is underneath the metal contact MT1. The p-type contact region 311 could be in any shape from top view, e.g., latticed, circular. The p-type contact region 311 helps to reduce the reverse leakage and protect the Schottky junction from breakdown.

Under continuous (DC bias) operation, the embodiments in FIGS. 2 and 3 suppress the PNP base and associated collector currents. However, under transient conditions, additional base displacement currents associated with parasitic base junction capacitances charging and discharging could transiently turn on the parasitic PNP transistor Q1 more significantly until sufficient base recombination current flows to charge the junction up to approaching or reaching the continuous operation bias point.

FIG. 4 schematically shows a cross section view of a semiconductor structure of a power transistor 400 in accordance with an embodiment of the present invention. Compared with the transistor 200, the transistor 400 further comprising a p-implant guard ring region inserted to the n-type isolation region 103 to split the n-type isolation region into a first part 403 and a second part 404, wherein the first part 403 of the n-type isolation region 103 is between the first p-implant region and the p-implant guard ring region, and the second part 404 of the n-type isolation region comprises the rest of the n-type isolation region 103, as shown in FIG. 4. In FIG. 4, the p-implant guard ring region comprises a p-well region 406 and a p-type buried layer 405. The first part 403 of the n-type isolation region comprises a contact region 408 under the metal contact MT6; and the second part 404 of the n-type isolation region comprises the Schottky contact region 201 under the metal contact MT1, wherein the metal contact MT1 is coupled to the input voltage Vin.

In some embodiments, the p-implant guard ring region may comprise only p-well region 406, i.e., the p-type buried layer 405 is replaced by the p-well region. In the example of FIG. 4, the p-implant guard ring region is coupled to the n-type isolation region 403 through the contact regions 407, 408, and the metal contacts MT5 and MT6.

In FIG. 4, the p-implant guard ring region is inserted to mitigate the before mentioned base displacement currents associated with parasitic base junction capacitances charging and discharging. The p-implant guard ring region acts as a false collector to divert some of the displacement currents that would otherwise escape to the enclosing second p-implant region instead into the base, thus speeding the time for the base of the PNP transistor Q1 to charge up, and reducing the time to approach the equilibrium continuous operation blocking state.

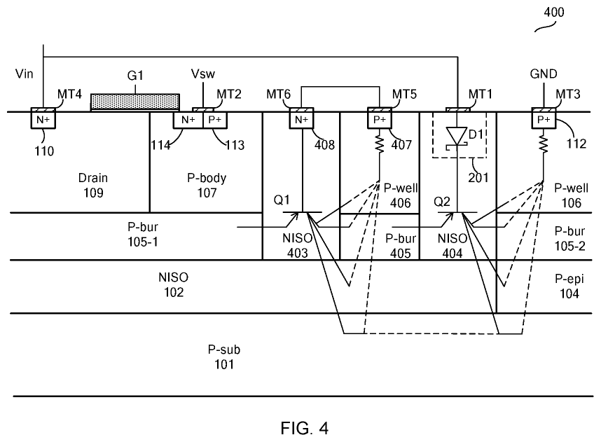

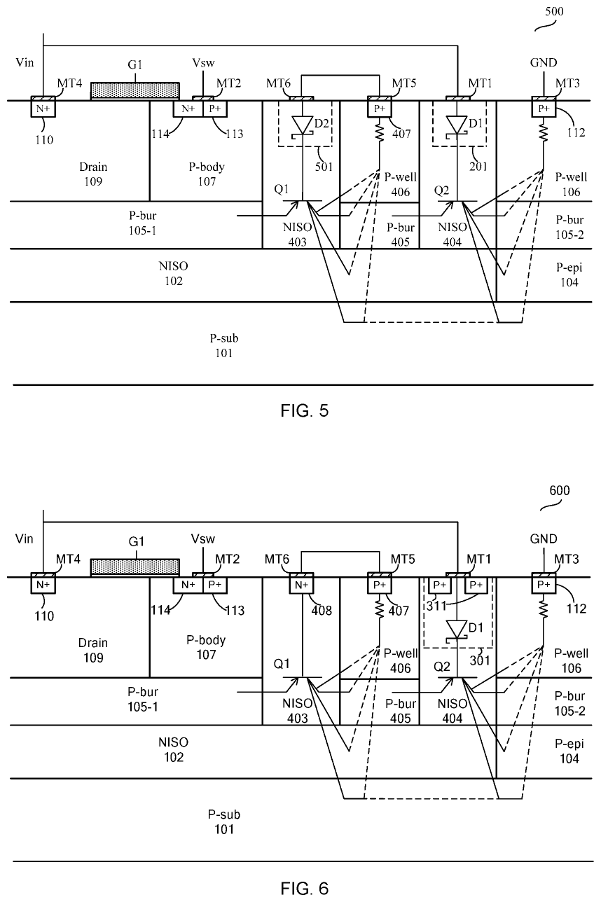

FIG. 5 schematically shows a cross section view of a semiconductor structure of a power transistor 500 in accordance with an embodiment of the present invention. In the example of FIG. 5, the first part 403 of the n-type isolation region comprises a second Schottky contact region 501 under the metal contact MT6; and the second part 404 of the n-implant region comprises the Schottky contact region 201. The Schottky contact region 501 further suppress the conductance of the PNP transistor Q1.

FIG. 6 schematically shows a cross section view of a semiconductor structure of a power transistor 600 in accordance with an embodiment of the present invention. In the example of FIG. 6, the second part 404 of the n-type isolation region further comprises a p-type contact region 311 located in a surface of the second part 404 of the n-type isolation region, wherein part of the p-type contact region 311 is underneath the metal contact MT1. In other embodiments, the whole part of the p-type contact region 311 could be underneath the metal contact MT1.

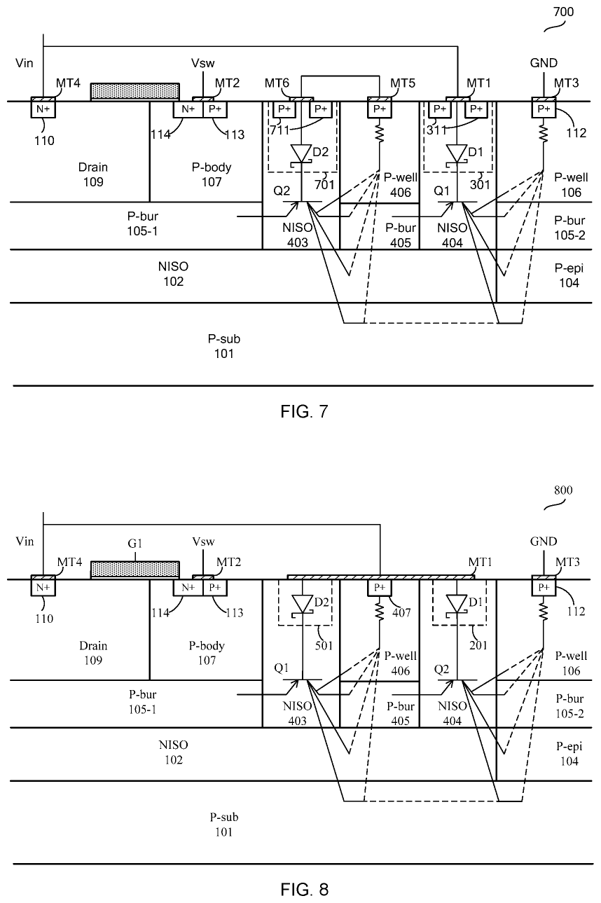

FIG. 7 schematically shows a cross section view of a semiconductor structure of a power transistor 700 in accordance with an embodiment of the present invention. Compared with the transistor 600 in FIG. 6, the first part 403 of the n-type isolation region in FIG. 7 comprises a second Schottky contact region 701 under the metal contact MT6, wherein the first part 403 of the n-type isolation region further comprises a p-type contact region 711 located in a surface of the second part 403 of the n-type isolation region, and wherein part of the p-type contact region 711 is underneath the metal contact MT6. In some embodiments, the p-type contact region 711 could be omitted.

FIG. 8 schematically shows a cross section view of a semiconductor structure of a power transistor 800 in accordance with an embodiment of the present invention. In the example of FIG. 8, the metal contact MT1 of Schottky contact region 201 is extended to first part 403 of the n-type isolation region, the second part 404 of the n-type isolation region and the p-implant guard ring region, wherein the p-implant guard ring region comprises the p-type contact region 407 underneath the metal contact MT1.

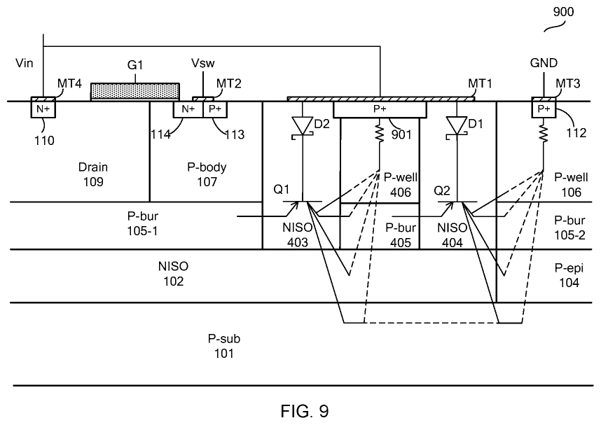

FIG. 9 schematically shows a cross section view of a semiconductor structure of a power transistor 900 in accordance with an embodiment of the present invention. In the example of FIG. 9, a p-type contact region 901 of the p-implant guard ring region is extended to the first part 403 and the second part 404 of the n-type isolation region, to help increase the breakdown voltage of the Schottky diodes D1 and D2.

While the above Detailed Description describes certain embodiments, the present invention is not limited to the features described and may be practice in many ways. Details of the system may vary in implementation, while still being encompassed by the present invention disclosed herein. Accordingly, the scope of the present invention encompasses not only the disclosed embodiments, but also all equivalent ways of practicing or implementing the present invention under the claims.

I/We claim:

1. A power transistor comprising:
a p-body region, coupled to a first voltage;
a first p-type buried layer under the p-body region;
a n-implant region surrounding the p-body region and the p-type buried layer;
a p-implant region surrounding the n-implant region; and
a p-implant guard ring region inserted into the n-implant region to split the n-implant region to a first part and a second part, wherein the first part of the n-implant region is between the p-body region and the p-implant guard ring region, and the second part of the n-implant region is between the p-implant guard ring region and the p-implant region; wherein
the second part of the n-implant region has a Schottky contact region coupled to a second voltage via a metal contact.

2. The power transistor of claim 1, wherein the p-implant region comprises:
a p-type substrate;
a second p-type buried layer above the p-type substrate; and
a p-well region above the second p-type buried layer.

3. The power transistor of claim 2, wherein the p-implant region further comprising a p-type epitaxial layer between the second p-type buried layer and the p-type substrate.

4. The power transistor of claim 1, further comprising a p-type contact region located in a top surface of the second part of the n-implant region, wherein part of the p-type contact region is underneath the metal contact of the second part of the n-implant region.

5. A power transistor comprising:
a first p-implant region, coupled to a first voltage;
a n-implant region surrounding the p-implant region, coupled to a second voltage; and
a second p-implant region surrounding the n-implant region; wherein
the n-implant region has a Schottky contact region coupled to the second voltage via a metal contact.

6. The power transistor of claim 5, wherein the first p-implant region comprises a p-body region and a p-type buried layer, wherein the p-body region is located between a drain region of the power transistor and the n-implant region, and the p-type buried layer is underneath the p-body region.

7. The power transistor of claim 5, wherein the second p-implant region comprises a p-type substrate, a p-type buried layer, and a p-type well region.

8. The power transistor of claim 5, wherein the n-implant region comprises a n-type isolation layer above a p-type substrate, and a n-type isolation region above the n-type isolation layer, wherein the n-type isolation region is between the first p-implant region and the second p-implant region.

9. The power transistor of claim 5, wherein the n-implant region further comprises a p-type contact region located in a top surface of the n-implant region, wherein part of the p-type contact region is underneath the metal contact of the n-implant region.

10. A power transistor comprising:
a first p-implant region, coupled to a first voltage;
a n-implant region surrounding the p-implant region, coupled to a second voltage;
a second p-implant region surrounding the n-implant region; and
a p-implant guard ring region inserted into the n-implant region to split the n-implant region into a first part and a second part, wherein the first part of the n-implant region is between the first p-implant region and the p-implant guard ring region, and the second part of the n-implant region is between the p-implant guard ring region and the second p-implant region; wherein
the second part of the n-implant region has a first Schottky contact region coupled to the second voltage via a metal contact.

11. The power transistor of claim 10, wherein a metal contact of the p-implant guard ring region is coupled to a metal contact of the first part of the n-implant region.

12. The power transistor of claim 10, wherein the first part of the n-implant region comprises a n-type contact region under a metal contact of the first part of the n-implant region.

13. The power transistor of claim 10, wherein the second part of the n-implant region further comprises a p-type contact region located in a top surface of the second part of the n-implant region, wherein part of the p-type contact region is underneath the metal contact of the second part of the n-implant region.

14. The power transistor of claim 10, wherein the first part of the n-implant region comprises a second Schottky contact region under a metal contact of the first part of the n-implant region.

15. The power transistor of claim 14, wherein the first part of the n-implant region further comprises a p-type contact region located in a top surface of the second part of the n-implant region, wherein part of the p-type contact region is underneath the metal contact of the first part of the n-implant region.

16. The power transistor of claim 14, wherein the second part of the n-implant region further comprises a p-type contact region located in a top surface of the second part of the n-implant region, wherein part of the p-type contact region is underneath the metal contact of the second part of the n-implant region.

17. The power transistor of claim 10, wherein the metal contact of the first Schottky contact region is extended to the first part of the n-implant region, the second part of the n-implant region and the p-implant guard ring region.

18. The power transistor of claim 17, wherein the p-implant guard ring region comprises a p-type contact region under a metal contact of the p-implant guard ring region.

19. The power transistor of claim 18, wherein the p-implant contact region of the p-type guard ring region is extended to the second part of the n-implant region.

20. The power transistor of claim 18, wherein:
the first part of the n-implant region has a second Schottky contact region under the metal contact of the first part of the n-implant region; and
the p-type contact region of the p-implant guard ring region is extended to the first part of the n-implant region.
